(19) United States
(12) Patent Application Publication
(10) Pub. No.: US 2024/0412950 A1
(43) Pub. Date: Dec. 12, 2024

(54) REACTION CHAMBER AND OXIDATION DEVICE

(71) Applicant: Beijing E-Town Semiconductor Technology Co., Ltd., Beijing (CN)

(72) Inventors: Jianmin JI, Beijing (CN); Haiwei LI, Beijing (CN); Wenxue SU, Beijing (CN)

(21) Appl. No.: 18/676,845

(22) Filed: May 29, 2024

(30) Foreign Application Priority Data
Jun. 6, 2023 (CN) 202310659848.4

(51) Int. Cl. H01J 37/32

(52) U.S. Cl. CPC H01J 37/3244; H01J 2237/338

(57) ABSTRACT

Provided is a reaction chamber and an oxidation device. The reaction chamber includes a chamber body and a flow guide tube. The chamber body is provided with a wafer stage inside, the wafer stage forms a reaction area for accommodating a wafer, a top surface of the reaction area is not lower than a top surface of the wafer, and a side wall of the chamber body is provided with an opening. The flow guide tube is arranged inside the chamber body, the flow guide tube comprises a tube body, a gas inlet of the tube body is communicated with the opening, and a gas outlet of the tube body extends toward the reaction area and is used to transport the plasma to the top surface of the reaction area.

### CROSS-REFERENCE TO RELATED APPLICATIONS

The present application claims priority to Chinese Patent Application No. CN202310659848.4, filed with the China National Intellectual Property Administration on Jun. 6, 2023, the disclosure of which is hereby incorporated herein by reference in its entirety.

### TECHNICAL FIELD

The present disclosure relates to the field of semiconductor technology, and in particular to a reaction chamber and an oxidation device.

### BACKGROUND

When the wafer undergoes the oxidation process, the gas mixture (microwave plasma) of oxygen and hydrogen is dissociated into a plasma rich in oxygen free radicals through a microwave plasma source, the plasma enters a reaction chamber, and silicon dioxide is generated on the wafer surface. The concentration of oxygen free radicals and their distribution on the wafer surface have a direct impact on the growth rate of silicon dioxide.

### SUMMARY

The present disclosure provides a reaction chamber and an oxidation device.

According to an aspect of the present disclosure, provided is a reaction chamber, including a chamber body and a flow guide tube.

The chamber body is provided with a wafer stage inside, the wafer stage forms a reaction area for accommodating a wafer, a top surface of the reaction area is not lower than a top surface of the wafer, and a side wall of the chamber body is provided with an opening for transporting a plasma into the chamber body.

The flow guide tube is arranged inside the chamber body, the flow guide tube includes a tube body, a gas inlet at one end of the tube body is communicated with the opening, and a gas outlet at other end of the tube body extends toward the reaction area and is used to transport the plasma to the top surface of the reaction area so that the plasma reacts with the top surface of the wafer.

According to another aspect of the present disclosure, provided is an oxidation device, including:
a reaction chamber according to any embodiment of the present disclosure; and
a plasma source arranged outside the reaction chamber, where a plasma output port of the plasma source is communicated with the opening.

According to the solution of the present disclosure, since the flow guide tube is arranged between the opening and the wafer stage, the plasma entering the interior of the chamber body through the opening can be converged to the top surface of the wafer via the transportation of the flow guide tube, avoiding the plasma from diffusing to areas outside the top surface of the wafer, increasing the plasma concentration on the top surface of the wafer, and thereby improving the growth rate of silicon dioxide generated on the top surface of the wafer and the quality of the generated silicon dioxide.

It should be understood that the content described in this summary is not intended to limit critical or essential features of embodiments of the present disclosure, nor is it used to limit the scope of the present disclosure. Other features of the present disclosure will be easily understood through the following description.

### BRIEF DESCRIPTION OF THE DRAWINGS

The above and other features, advantages and aspects of various embodiments of the present disclosure will become more apparent with reference to the following detailed description in combination with the accompanying drawings. In the accompanying drawings, the same or similar reference numbers represent the same or similar elements.

FIG. 1 is a schematic structural diagram of a reaction chamber according to an embodiment of the present disclosure;

FIG. 2 is a schematic structural diagram of a reaction chamber according to an embodiment of the present disclosure;

FIG. 3 is a schematic structural diagram of a reaction chamber according to an embodiment of the present disclosure;

FIG. 4 is a schematic structural diagram of a flow guide tube according to an embodiment of the present disclosure;

FIG. 5 is a schematic structural diagram of a flow guide tube according to an embodiment of the present disclosure;

FIG. 6 is a schematic structural diagram of a flow guide tube according to an embodiment of the present disclosure;

FIG. 7 is a schematic structural diagram of a flow guide tube according to an embodiment of the present disclosure;

FIG. 8 is a schematic structural diagram of an oxidation device according to an embodiment of the present disclosure;

FIG. 9 is a schematic structural diagram of an oxidation device according to an embodiment of the present disclosure; and

FIG. 10 is a schematic structural diagram of an oxidation device according to an embodiment of the present disclosure.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope and spirit of the present disclosure. Likewise, for clarity and conciseness, descriptions of well-known functions and structures are omitted in the following descriptions.

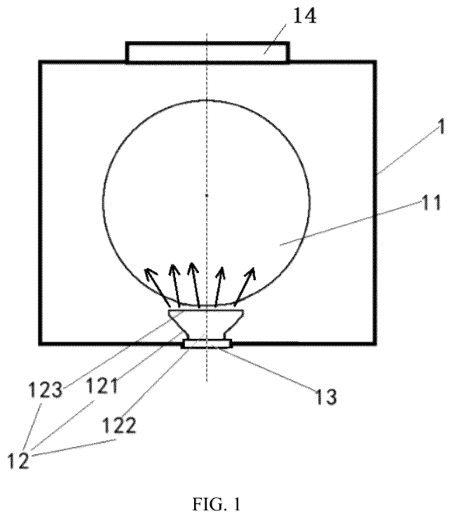

An embodiment of the present disclosure provides a reaction chamber, as shown in FIGS. 1 to 3, including a chamber body 1 and a flow guide tube 12.

The chamber body 1 is provided with a wafer stage 11 inside, the wafer stage 11 forms a reaction area 111 for accommodating a wafer, a top surface of the reaction area 111 is not lower than a top surface of the wafer, and a side wall of the chamber body 1 is provided with an opening 13 for transporting a plasma into the chamber body 1.

The flow guide tube 12 is arranged inside the chamber body 1, the flow guide tube 12 includes a tube body 121, a gas inlet 122 at one end of the tube body 121 is communicated with the opening 13, and a gas outlet 123 at other end of the tube body 121 extends toward the reaction area 111 and is used to transport the plasma to the top surface of the reaction area 111 so that the plasma reacts with the top surface of the wafer.

According to the embodiment of the present disclosure, it should be noted that:

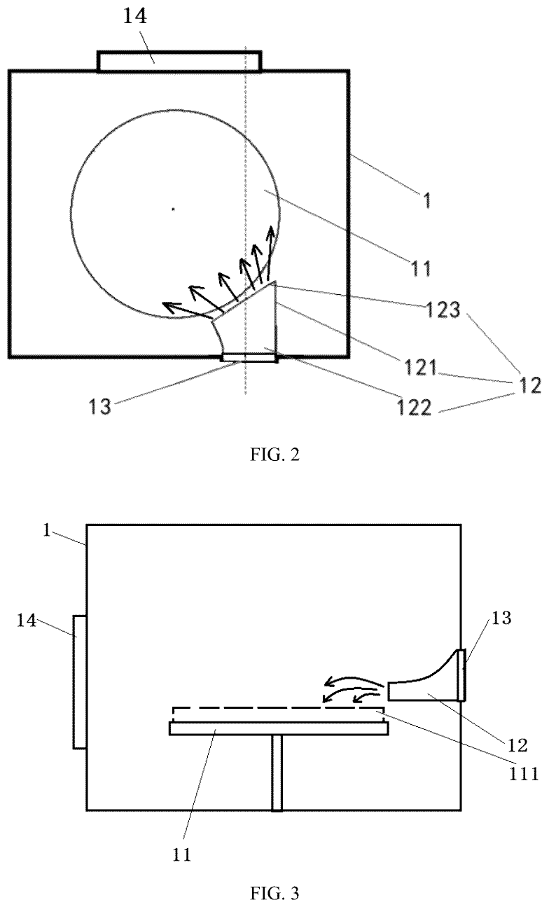

FIGS. 1 and 2 are top views of the reaction chamber. The left-right direction and the up-down direction of the reaction chamber in FIGS. 1 and 2 are defined as the width direction of the chamber body 1, and the front-back direction of the reaction chamber in FIGS. 1 and 2 is defined as the height direction of the chamber body 1.

FIG. 3 is a side view of the reaction chamber. The left-right direction of the reaction chamber in FIG. 3 is defined as the width direction of the chamber body 1, and the up-down direction of the reaction chamber in FIG. 3 is defined as the height direction of the chamber body 1.

The interior of the chamber body I may be understood as the space formed by the inner wall of the chamber body 1 for the wafer to undergo the oxidation reaction. The shape and size of the interior of the chamber body 1 may be selected and adjusted as needed and are not specifically limited here. For example, the interior of the chamber body 1 may be a rectangular structure, a cylindrical structure or a prismatic structure.

The location of the wafer stage 11 inside the chamber body 1 may be selected and adjusted as needed. For example, the wafer stage 11 may be placed horizontally in the width direction of the chamber body 1, and the wafer stage 11 may be spatially arranged below the opening 13 or arranged substantially horizontally with the opening 13.

The arrangement of the wafer stage 11 in the chamber body 1 may be selected and adjusted as needed. For example, the wafer stage 11 is rotatably arranged in the chamber body 1 so that the plasma transported by the flow guide tube 12 can be evenly distributed on the top surface of the wafer; and/or, the wafer stage 11 may be raised and lowered in the chamber body 1 so that the height position of the wafer stage 11 can be adjusted relative to the gas outlet 123 of the flow guide tube 12, to make the plasma transported by the flow guide tube 12 be transported to the top surface of the wafer as much as possible without leaking to areas outside the top surface of the wafer.

The reaction area 111 can be understood as a designed space located on the upper end surface of the wafer stage 11, and this space is used to enable the wafer to be completely accommodated therein.

The wafer stage 11 is formed with the reaction area 111 for accommodating the wafer, and the top surface of the reaction area 111 is not lower than the top surface of the wafer, which can be understood as: the outer edge of the reaction area 111 is equivalent to the outer edge of the wafer, and the top surface of the reaction area 111 is equivalent to the top surface of the wafer or higher than the top surface of the wafer. That is to say, the reaction area 111 can completely cover the wafer.

The side wall of the chamber body 1 is provided with the opening 13, which can be understood as: the opening 13 is provided at any position on any side wall of the chamber body 1. Here, the shapes and sizes of the opening 13, the plasma output port of the plasma source 2 and the gas outlet 123 are matched.

The gas inlet 122 and the gas outlet 123 of the flow guide tube 12 are communicated, and the plasma output port of the plasma source 2 transports the plasma to the reaction area 111 inside the chamber body 1 after passing through the opening 13 of the side wall, the gas inlet 122 of the tube body 121, and the gas outlet 123 of the tube body 121 in sequence.

The gas outlet 123 at the other end of the tube body 121 extends toward the reaction area 111, and the relative position relationship between the gas outlet 123 and the reaction area 111 may be selected and adjusted as needed. For example, the gas outlet 123 extends to a position where the lower edge of the gas outlet 123 is above the top surface of the reaction area 111, and the gas outlet 123 extends to a position where the end surface of the gas outlet 123 is outside the edge of the reaction area 111. For example, the gas outlet 123 extends to a position where the lower edge of the gas outlet 123 is flush with the top surface of the reaction area 111, and the gas outlet 123 extends to a position where the end surface of the gas outlet 123 is outside the edge of the reaction area 111. For example, the gas outlet 123 extends to a position where the lower edge of the gas outlet 123 is above the top surface of the reaction area 111, and the gas outlet 123 extends to a position where the end surface of the gas outlet 123 is tangent to the edge of the reaction area 111. For example, the gas outlet 123 extends to a position where the lower edge of the gas outlet 123 is flush with the top surface of the reaction area 111, and the gas outlet 123 extends to a position where the end surface of the gas outlet 123 is tangent to the edge of the reaction area 111.

The shape of the tube body 121 may be selected and adjusted as needed. For example, the size of one end of the tube body 121 close to the gas outlet 123 in the width direction of the chamber body 1 is larger than the size of one end of the tube body 121 close to the gas inlet 122 in the width direction of the chamber body 1, thereby facilitating the plasma to diffuse outward from the gas outlet 123 over a larger area.

The material of the flow guide tube 12 may be selected and adjusted as needed. For example, the flow guide tube 12 may be made of quartz to avoid affecting the generation quality of silicon dioxide during wafer reaction.

When the wafer undergoes the oxidation process, the gas mixture of oxygen and hydrogen as reaction gases is dissociated into a plasma rich in oxygen free radicals through the plasma source 2, and then the plasma is transported into the chamber body 1 through the flow guide tube 12 and gathered onto the top surface of the wafer, thereby generating a high-quality oxide film of silicon dioxide on the top surface of the wafer.

According to the embodiment of the present disclosure, the flow guide tube 12 communicated with the opening 13 is arranged inside the chamber body 1, reducing the gap between the opening 13 and the wafer; and the plasma entering the chamber body 1 through the opening 13 can be directly guided to the top surface of the wafer via the flow guide tube 12, avoiding the plasma from diffusing and leaking to areas outside the top surface of the wafer after entering the chamber body 1, and reducing the loss of plasma transported to the chamber body 1. At the same time, since the plasma is directly gathered onto the top surface of the wafer, the plasma concentration on the top surface of the wafer can be increased, thereby increasing the growth rate of the silicon dioxide film on the top surface of the wafer.

In one example, the interior of the chamber body 1 is set to a low-pressure environment, and the internal air pressure may be less than 20 Torrs.

According to the embodiment of the present disclosure, the plasma will not diffuse freely after entering the interior of the chamber body 1 in the reaction chamber in the low-pressure environment. Therefore, the plasma is directly transported to the reaction area 111 through the flow guide tube 12, so that the plasma can be gathered on the top surface of the wafer without diffusing to areas outside the top surface of the wafer, increasing the plasma concentration on the top surface of the wafer, and thereby increasing the growth rate of the oxide film of silicon dioxide on the top surface of the wafer.

In one example, the process environment of the reaction chamber at least meets any one or any combination of: the process temperature of 600° C. to 1200° C., the process pressure less than 20 Torrs, the gas flow rate of 1 SLM (Standard Liter per Minute) to 30 SLMs, and the gas mixture of hydrogen and oxygen dissociated into plasma rich in oxygen free radicals (hydrogen ratio is less than 30%).

In one embodiment, the lower edge of the gas outlet 123 is located above the top surface of the reaction area 111, and the end surface of the gas outlet 123 is located outside the edge of the reaction area 111. That is, the top surface of the reaction area 111 is located obliquely below the lower edge of the gas outlet 123.

According to the embodiment of the present disclosure, it should be noted that:

The lower edge of the gas outlet 123 can be understood as the edge of the gas outlet 123 close to the reaction area 111.

The end surface of the gas outlet 123 can be understood as a plane surrounded by the outer edge contour of the gas outlet 123.

According to the embodiment of the present disclosure, the gas outlet 123 is arranged at a position obliquely above the top surface of the reaction area 111. After the plasma enters the interior of the chamber body 1 through the guide tube 12, the plasma will be directly output from the gas outlet 123 to the top surface of the reaction area 111, avoiding the plasma from diffusing to the bottom surface of the wafer or the outside of the wafer, and simultaneously avoiding the gas outlet 123 from contacting the wafer.

In one embodiment, the vertical distance between the lower edge of the gas outlet 123 and the top surface of the reaction area 111 is 2 mm to 5 mm in the height direction of the chamber body 1; and the horizontal distance between the end surface of the gas outlet 123 and the outer edge of the reaction area 111 is 2 mm to 5 mm in the width direction of the chamber body 1.

According to the embodiment of the present disclosure, the gas outlet 123 is arranged at a position obliquely above the top surface of the reaction area 111. After the plasma enters the interior of the chamber body 1 through the guide tube 12, the plasma will be directly output from the gas outlet 123 to the top surface of the reaction area 111, avoiding the plasma from diffusing to the bottom surface of the wafer or the outside of the wafer, and simultaneously avoiding the gas outlet 123 from contacting the wafer.

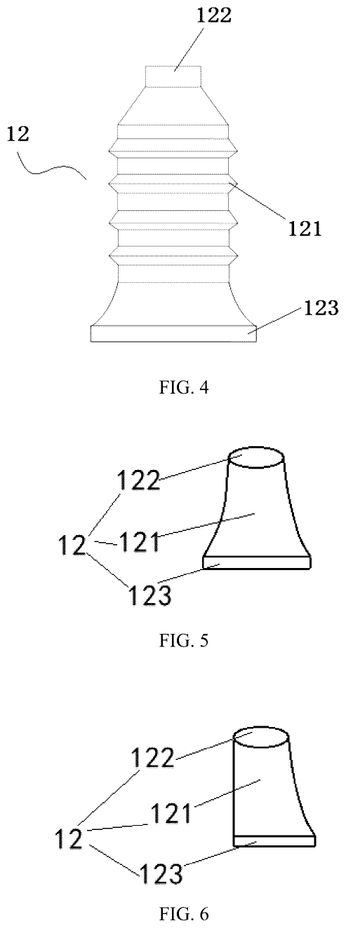

In one embodiment, as shown in FIG. 4, the tube body 121 is a flexible and retractable tube body 121, and/or, the gas outlet 123 is rotatably connected to the tube body 121.

According to the embodiment of the present disclosure, it should be noted that:

The flexible and retractable tube body 121 can be understood as: the portion of the tube body 121 between the gas inlet 122 and the gas outlet 123 can be adjusted in length and bending posture as needed. For example, the gas outlet 123 is facing the wafer by stretching or bending the tube body 121.

The gas outlet 123 is rotatably connected to the tube body 121, which can be understood as: the gas outlet 123 can swing independently relative to the tube body 121, so as to adjust the orientation of the gas outlet 123.

According to the embodiment of the present disclosure, the relative position relationship between the gas outlet 123 and the wafer can be adjusted, so that plasma can be directly output from the gas outlet 123 of the flow guide tube 12 to the top surface of the wafer.

In one embodiment, as shown in FIGS. 1 to 3, the chamber body 1 is further provided with a wafer placement opening 14 for placing or taking out the wafer.

In one embodiment, as shown in FIG. 1, the central axis of the opening 13 intersects with the central axis of the wafer stage 11 and is parallel to the central axis of the end surface of the gas outlet 123, the end surface of the gas outlet 123 is parallel to the plane where the opening 13 is located, and two side edges of the gas outlet 123 in the width direction of the chamber body 1 are symmetrically arranged relative to the central axis of the wafer stage 11.

According to the embodiment of the present disclosure, it should be noted that:

The end surface of the gas outlet 123 is parallel to the plane where the opening 13 is located, which can be understood as: if the opening 13 is an arc-shaped hole (the sides of the opening 13 are not in the same vertical plane), the gas outlet 123 is an arc-shaped opening. If the opening 13 is a plane hole (all sides of the opening 13 are located in the same vertical plane), the gas outlet 123 is a plane opening. Alternatively, the opening 13 is a plane hole (all sides of the opening 13 are located in the same vertical plane), and the gas outlet 123 is an arc-shaped opening (the sides of the gas outlet 123 are not in the same vertical plane, but the projections of the sides of the gas outlet 123 on the vertical plane where one of the sides is located is parallel to the plane where the opening 13 is located).

The two side edges of the gas outlet 123 in the width direction of the chamber body 1 are symmetrically arranged relative to the central axis of the wafer stage 11, which can be understood as: the cross-sectional shape of the gas outlet 123 is a bilaterally symmetrical shape, such as a circle, a square, or any bilaterally symmetrical shape. In this way, the distances from the left and right sides of the gas outlet 123 to the edge of the wafer stage 11 or the reaction area 111 can be equal, ensuring that the plasma is uniformly output from the gas outlet 123 to the top surface of the wafer. Here, the width of the gas outlet 123 may be selected and adjusted as needed. For example, the width of the gas outlet 123 is equal to the width of the gas inlet 122, or the width of the gas outlet 123 is greater than the width of the gas inlet 122.

According to the embodiment of the present disclosure, the gas outlet 123 is arranged opposite to the wafer so that the areas of plasmas output on the left and right sides of the gas outlet 123 are the same, thereby allowing the plasma to be uniformly output from the gas outlet 123 to the top surface of the wafer, and improving the uniformity of the generated silicon dioxide.

In one embodiment, as shown in FIGS. 1 and 5, the central axis of the opening 13 intersects with the central axis of the wafer stage 11 and is parallel to the central axis of the end surface of the gas outlet 123, the end surface of the gas outlet 123 is parallel to the plane where the opening 13 is located, and two side edges of the gas outlet 123 in the width direction of the chamber body 1 are symmetrically arranged relative to the central axis of the wafer stage 11. The tube body 121 is a gradually expanding structure that is axisymmetric in its length direction, an expanded end of the tube body 121 forms the gas outlet 123, and a contracted end of the tube body 121 forms the gas inlet 122, where the diameter of the gas outlet 123 in the width direction of the chamber body 1 is larger than the diameter of the gas inlet 122 in the width direction of the chamber body 1.

According to the embodiment of the present disclosure, it should be noted that:

The diameter of the gas outlet 123 in the width direction of the chamber body 1 is larger than the diameter of the gas inlet 122 in the width direction of the chamber body 1, which can be understood as: the width of the gas outlet 123 is larger than the width of the gas inlet 122, the height of the gas outlet 123 is larger than the height of the gas inlet 122, and the end of the gas outlet 123 presents a diffusion end with a larger diameter; or, the width of the gas outlet 123 is larger than the width of the gas inlet 122, the height of the gas outlet 123 is equal to the height of the gas inlet 122, and the end of the gas outlet 123 presents a flat diffusion end with a highly same diameter; or, the width of the gas outlet 123 is larger than the width of the gas inlet 122, and the height of the gas outlet 123 is smaller than the height of the gas inlet 122, and the end of the gas outlet 123 presents a flat diffuser end with a smaller diameter.

According to the embodiment of the present disclosure, the plasma sprayed from the gas outlet 123 can cover a larger area on the top surface of the wafer by increasing the width of the gas outlet 123, thereby allowing the plasma to contact the top surface of the wafer in a larger area, and increasing the plasma concentration on the top surface of the wafer.

In one embodiment, as shown in FIG. 2, the central axis of the opening 13 is staggered with the central axis of the wafer stage 11, and the end surface of the gas outlet 123 is parallel to the height direction of the chamber body 1 and inclined relative to the end surface of the opening 13.

According to the embodiment of the present disclosure, it should be noted that:

The central axis of the opening 13 is staggered with the central axis of the wafer stage 11, which can be understood as: the opening 13 is not directly opposite to the wafer stage 11, that is, the partial extended area of the opening 13 overlaps with the area on the top of the wafer stage 11, or the extended area of the opening 13 is not located outside the area on the top of the wafer stage 11.

The end surface of the gas outlet 123 is parallel to the height direction of the chamber body 1, which can be understood as: all sides of the gas outlet 123 are located on the same vertical plane, and this vertical plane is parallel to the height of the chamber body 1. That is to say, the plane where the gas outlet 123 is located is perpendicular to the plane where the wafer stage 11 is located.

The end surface of the gas outlet 123 is inclined relative to the end surface of the opening 13, which can be understood as: the end surface of the gas outlet 123 can be rotated toward the center of the wafer stage 11 along the axis of the height direction of the chamber body 1, and the end surface of the gas outlet 123 after rotation is arranged at an angle with the end surface of the opening 13.

According to the embodiment of the present disclosure, when the opening 13 of the chamber body 1 is arranged away from the center position of the wafer stage 11, the plasma can be guided to the top surface of the wafer through the inclined gas outlet 123, so that the plasma will not be affected by the position of the opening 13 when being input into the chamber body 1, and the plasma can still be completely guided to the top surface of the wafer without leaking to the areas outside the top surface of the wafer, ensuring that the high-concentration plasma is gathered on the top surface of the wafer.

In one example, as shown in FIG. 2, when the central axis of the opening 13 is located on a first side of the central axis of the wafer stage 11, the end surface of the gas outlet 123 is parallel to the height direction of the chamber body 1 and inclined toward a second side relative to the end surface of the opening 13, where the second side is opposite to the first side. Preferably, the plane on the left side of the gas outlet 123 intersects with the extended area on the top of the wafer stage 11, and the plane on the right side of the gas outlet 123 is tangent to the edge of the extended area on the top of the wafer stage 11. Such arrangement can reduce the free diffusion of the plasma output from the right side of the gas outlet 123.

In one embodiment, as shown in FIGS. 2 and 6, the central axis of the opening 13 is staggered with the central axis of the wafer stage 11, and the end surface of the gas outlet 123 is parallel to the height direction of the chamber body 1 and inclined relative to the end surface of the opening 13. The tube body 121 is a gradually expanding structure that is asymmetric in its length direction, an expanded end of the tube body 121 forms the gas outlet 123, and a contracted end of the tube body 121 forms the gas inlet 122, where the diameter of the gas outlet 123 in the width direction of the chamber body 1 is larger than the diameter of the gas inlet 122 in the width direction of the chamber body 1. The tube wall of the tube body 121 on one side close to the central axis of the wafer stage 11 is an arc-shaped tube wall, and this tube wall is bent toward the central axis of the wafer stage 11. The tube wall of the tube body 121 on one side away from the central axis of the wafer stage 11 is an arc-shaped or straight tube wall. When this tube wall is an arc-shaped tube wall, this tube wall is bent toward the direction away from the central axis of the wafer stage 11.

According to the embodiment of the present disclosure, it should be noted that:

The diameter of the gas outlet 123 in the width direction of the chamber body 1 is larger than the diameter of the gas inlet 122 in the width direction of the chamber body 1, which can be understood as: the width of the gas outlet 123 is larger than the width of the gas inlet 122, the height of the gas outlet 123 is larger than the height of the gas inlet 122, and the end of the gas outlet 123 presents a diffusion end with a larger diameter; or, the width of the gas outlet 123 is larger than the width of the gas inlet 122, the height of the gas outlet 123 is equal to the height of the gas inlet 122, and the end of the gas outlet 123 presents a flat diffusion end with a highly same diameter; or, the width of the gas outlet 123 is larger than the width of the gas inlet 122, and the height of the gas outlet 123 is smaller than the height of the gas inlet 122, and the end of the gas outlet 123 presents a flat diffuser end with a smaller diameter.

According to the embodiment of the present disclosure, the plasma sprayed from the gas outlet 123 can cover a larger area on the top surface of the wafer by increasing the width of the gas outlet 123, thereby allowing the plasma to contact the top surface of the wafer in a larger area, and increasing the plasma concentration on the top surface of the wafer.

In one embodiment, as shown in FIG. 7, the diameter of the gas outlet 123 in the height direction of the chamber body 1 is smaller than the diameter of the gas inlet 122 in the height direction of the chamber body 1.

According to the embodiment of the present disclosure, the gas outlet 123 with a smaller height is arranged, to increase the rate at which the plasma is output from the gas outlet 123 and avoid the plasma from diffusing to areas outside the top surface of the wafer after being output from the gas outlet 123.

In one embodiment, the central axis of the opening 13 intersects with the central axis of the wafer stage 11 and is parallel to the central axis of the end surface of the gas outlet 123, the end surface of the gas outlet 123 is parallel to the plane where the opening 13 is located, and two side edges of the gas outlet 123 in the width direction of the chamber body 1 are symmetrically arranged relative to the central axis of the wafer stage 11. The tube body 121 is a gradually expanding structure that is axisymmetric in its length direction, an expanded end of the tube body 121 forms the gas outlet 123, and a contracted end of the tube body 121 forms the gas inlet 122, where the diameter of the gas outlet 123 in the width direction of the chamber body 1 is larger than the diameter of the gas inlet 122 in the width direction of the chamber body 1. The diameter of the gas outlet 123 in the height direction of the chamber body 1 is smaller than the diameter of the gas inlet 122 in the height direction of the chamber body 1.

In one embodiment, the central axis of the opening 13 is staggered with the central axis of the wafer stage 11, and the end surface of the gas outlet 123 is parallel to the height direction of the chamber body 1 and inclined relative to the end surface of the opening 13. The tube body 121 is a gradually expanding structure that is asymmetric in its length direction, an expanded end of the tube body 121 forms the gas outlet 123, and a contracted end of the tube body 121 forms the gas inlet 122, where the diameter of the gas outlet 123 in the width direction of the chamber body 1 is larger than the diameter of the gas inlet 122 in the width direction of the chamber body 1. The diameter of the gas outlet 123 in the height direction of the chamber body 1 is smaller than the diameter of the gas inlet 122 in the height direction of the chamber body 1.

In one embodiment, the diameter of the gas outlet 123 in the height direction of the chamber body 1 is smaller than the diameter of the gas inlet 122 in the height direction of the chamber body 1. The diameter of the gas outlet 123 in the width direction of the chamber body 1 is equal to the diameter of the gas inlet 122 in the width direction of the chamber body 1.

In one embodiment, as shown in FIG. 5, the gas outlet 123 may be of a flat mouth shape; and/or, the gas inlet 122 may be of a circle shape.

According to the embodiment of the present disclosure, the width of the gas outlet 123 can be increased by arranging the gas outlet 123 in flat mouth shape, so that the area of the lateral cross-section of the gas outlet 123 to output the plasma becomes larger, thereby allowing the plasma to contact the top surface of the wafer in a larger area, and increasing the plasma concentration on the top surface of the wafer. The circular plasma output port of the plasma source 2 can be better adapted by arranging the gas inlet 122 in circle shape.

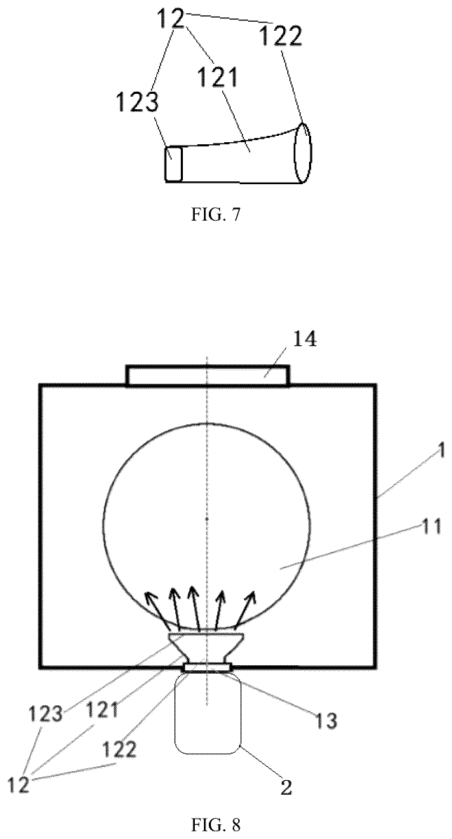

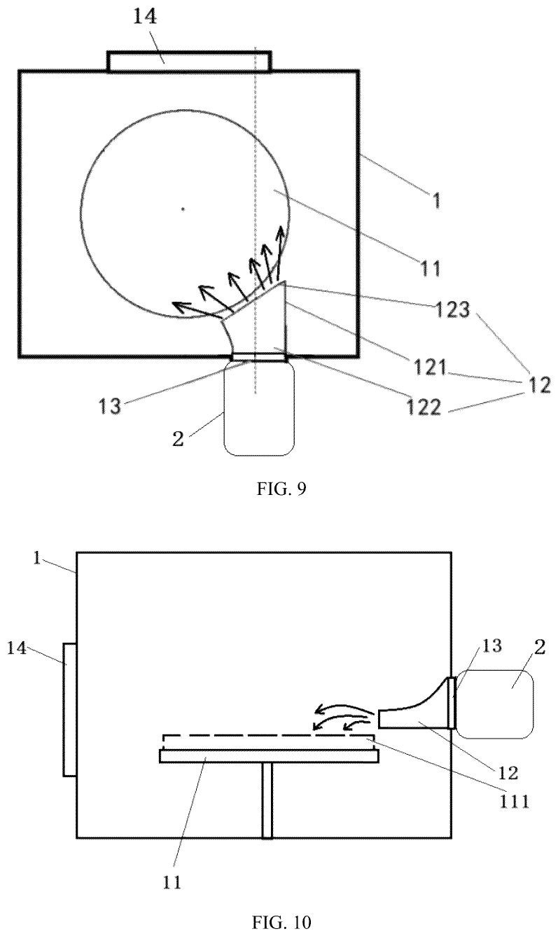

As shown in FIG. 8 to FIG. 10, an embodiment of the present disclosure provides an oxidation device, including a plasma source 2 and a reaction chamber of any one of the above embodiments.

The plasma source 2 is arranged outside the reaction chamber, and a plasma output port of the plasma source 2 is communicated with the opening 13.

According to the embodiment of the present disclosure, it should be noted that:

The plasma source 2 can be understood as a plasma generator of any structure in the prior art.

According to the embodiment of the present disclosure, the flow guide tube 12 communicated with the opening 13 is arranged inside the chamber body 1, reducing the gap between the opening 13 and the wafer; and the plasma entering the chamber body 1 through the opening 13 can be directly guided to the top surface of the wafer via the flow guide tube 12, avoiding the plasma from diffusing and leaking to areas outside the top surface of the wafer after entering the chamber body 1, and reducing the loss of plasma transported to the chamber body 1. At the same time, since the plasma is directly gathered onto the top surface of the wafer, the plasma concentration on the top surface of the wafer can be increased, thereby increasing the growth rate of the silicon dioxide film on the top surface of the wafer.

In one example, the oxidation device of the embodiment of the present disclosure includes: a plasma source 2 and a reaction chamber. A chamber body 1 of the reaction chamber is provided with a wafer stage 11 inside, the wafer stage 11 forms a reaction area 111 for accommodating a wafer, and a top surface of the reaction area 111 is not lower than a top surface of the wafer. The side wall of the chamber body 1 is provided with an opening 13, and the opening 13 is communicated with a plasma output port of the plasma source 2. A flow guide tube 12 of the reaction chamber is arranged inside the chamber body 1, the flow guide tube 12 includes a tube body 121, a gas inlet 122 at one end of the tube body 121 is communicated with the opening 13, and a gas outlet 123 at other end of the tube body 121 extends toward the reaction area 111 and is used to transport the plasma to the top surface of the reaction area 111 so that the plasma reacts with the top surface of the wafer.

In one example, the plasma source 2 of the oxidation device is installed on the side wall of the chamber body 1, the interior of the chamber body 1 is square in design, the internal gas pressure of the chamber body 1 is less than 20 Torrs, the outlet of the plasma source 2 is flush with the inner wall of the chamber body 1, the wafer is located in the center of the reaction chamber, and there is a gap between the wafer and the outlet of the plasma source 2. The ionized plasma flows from the outlet of the plasma source 2 to the upper surface (top surface) of the wafer for reaction after passing through the gap, so a part of the plasma will flow to the bottom of the wafer along the gap, thereby reducing the plasma concentration on the upper surface of the wafer. With the oxidation device of the present disclosure, the flow guide tube 12 is designed at the generator outlet of the plasma source 2, so that the plasma can be directly guided to the wafer surface through the flow guide tube 12, thereby avoiding the loss of plasma and increasing the growth rate of the oxide film (silicon dioxide).

In the description of this specification, it should be understood that the orientations or position relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axis”, “radial”, “circumferential”, etc. are orientations or position relationships shown based on the drawings, and are only for the purpose of facilitating the description of the present disclosure and simplifying the description, rather than indicating or implying that the device or element referred to must have a particular orientation or be constructed and operated in a particular orientation, and thus should not be construed as the limitation on the present disclosure.

Moreover, the terms “first” and “second” are only for the purpose of description, and cannot be construed to indicate or imply the relative importance or implicitly point out the number of technical features indicated. Therefore, the feature defined with “first” or “second” may explicitly or implicitly include one or more features. In the description of the present disclosure, “a plurality of” means two or more than two, unless otherwise expressly and specifically defined.

In the present disclosure, unless otherwise expressly specified and limited, the terms such as “install”, “couple”, “connect” and “fix” should be understood in broad sense. For example, it may be fixed connection or detachable connection or integral connection; may be mechanical connection or electrical connection or communication connection; may be direct connection, or indirect connection through an intermediate medium; may be internal communication between two elements or interaction relationship between two elements. Those having ordinary skill in the art may understand the specific meanings of the above-mentioned terms in the present disclosure according to specific situations.

In the present disclosure, unless otherwise expressly specified and defined, a first feature “above” or “below” a second feature may include: the first and second features are in direct contact, or the first and second features are not in direct contact but in contact through other features between them. Furthermore, the first feature “above”, “on” and “over” the second feature includes: the first feature is directly above and diagonally above the second feature, or simply means that the first feature is higher in level than the second feature. The first feature “below”, “under” and “underneath” the second feature includes: the first feature is directly below and diagonally below the second feature, or simply means that the first feature is lower in level than the second feature.

The above disclosure provides a number of different embodiments or examples to implement different structures of the present disclosure. To simplify the present disclosure, the components and arrangements of specific examples are described above. Of course, they are merely examples and are not intended to limit the present disclosure. Furthermore, the present disclosure may repeat reference numbers and/or reference letters in different examples, and such repetition is for purposes of simplicity and clarity and does not by itself indicate the relationship among various embodiments and/or arrangements discussed.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the spirit and principle of the present disclosure shall be included in the protection scope of the present disclosure.

What is claimed is:

1. A reaction chamber, comprising:
a chamber body provided with a wafer stage inside, wherein the wafer stage forms a reaction area for accommodating a wafer, a top surface of the reaction area is not lower than a top surface of the wafer, and a side wall of the chamber body is provided with an opening for transporting a plasma into the chamber body; and
a flow guide tube arranged inside the chamber body, wherein the flow guide tube comprises a tube body, a gas inlet at one end of the tube body is communicated with the opening, and a gas outlet at other end of the tube body extends toward the reaction area and is used to transport the plasma to the top surface of the reaction area so that the plasma reacts with the top surface of the wafer.

2. The reaction chamber of claim 1, wherein a lower edge of the gas outlet is located above the top surface of the reaction area, and an end surface of the gas outlet is located outside an edge of the reaction area.

3. The reaction chamber of claim 2, wherein a vertical distance between the lower edge of the gas outlet and the top surface of the reaction area is 2 mm to 5 mm in a height direction of the chamber body; and
a horizontal distance between the end surface of the gas outlet and an outer edge of the reaction area is 2 mm to 5 mm in a width direction of the chamber body.

4. The reaction chamber of claim 1, wherein the tube body is a flexible and retractable tube body; and/or the gas outlet is rotatably connected to the tube body.

5. The reaction chamber of claim 1, wherein the flow guide tube is made of quartz.

6. The reaction chamber of claim 1, wherein a central axis of the opening intersects with a central axis of the wafer stage and is parallel to a central axis of an end surface of the gas outlet, the end surface of the gas outlet is parallel to a plane where the opening is located, and two side edges of the gas outlet in a width direction of the chamber body are symmetrically arranged relative to the central axis of the wafer stage.

7. The reaction chamber of claim 6, wherein the tube body is a gradually expanding structure, an expanded end of the tube body forms the gas outlet, and a contracted end of the tube body forms the gas inlet, wherein a diameter of the gas outlet in the width direction of the chamber body is larger than a diameter of the gas inlet in the width direction of the chamber body.

8. The reaction chamber of claim 1, wherein a central axis of the opening is staggered with a central axis of the wafer stage, and an end surface of the gas outlet is parallel to a height direction of the chamber body and inclined relative to an end surface of the opening.

9. The reaction chamber of claim 8, wherein the tube body is a gradually expanding structure, an expanded end of the tube body forms the gas outlet, and a contracted end of the tube body forms the gas inlet, wherein a diameter of the gas outlet in the width direction of the chamber body is larger than a diameter of the gas inlet in the width direction of the chamber body.

10. The reaction chamber of claim 6, wherein a diameter of the gas outlet in the height direction of the chamber body is smaller than a diameter of the gas inlet in the height direction of the chamber body.

11. The reaction chamber of claim 10, wherein the gas outlet is of a flat mouth shape; and/or, the gas inlet is of a circle shape.

12. An oxidation device, comprising:
a reaction chamber, comprising:
a chamber body provided with a wafer stage inside, wherein the wafer stage forms a reaction area for accommodating a wafer, a top surface of the reaction area is not lower than a top surface of the wafer, and a side wall of the chamber body is provided with an opening for transporting a plasma into the chamber body; and
a flow guide tube arranged inside the chamber body, wherein the flow guide tube comprises a tube body, a gas inlet at one end of the tube body is communicated with the opening, and a gas outlet at other end of the tube body extends toward the reaction area and is used to transport the plasma to the top surface of the reaction area so that the plasma reacts with the top surface of the wafer; and
a plasma source arranged outside the reaction chamber, wherein a plasma output port of the plasma source is communicated with the opening.

13. The oxidation device of claim 12, wherein a lower edge of the gas outlet is located above the top surface of the reaction area, and an end surface of the gas outlet is located outside an edge of the reaction area.

14. The oxidation device of claim 13, wherein a vertical distance between the lower edge of the gas outlet and the top surface of the reaction area is 2 mm to 5 mm in a height direction of the chamber body; and
a horizontal distance between the end surface of the gas outlet and an outer edge of the reaction area is 2 mm to 5 mm in a width direction of the chamber body.

15. The oxidation device of claim 12, wherein the tube body is a flexible and retractable tube body; and/or the gas outlet is rotatably connected to the tube body.

16. The oxidation device of claim 12, wherein the flow guide tube is made of quartz.

17. The oxidation device of claim 12, wherein a central axis of the opening intersects with a central axis of the wafer stage and is parallel to a central axis of an end surface of the gas outlet, the end surface of the gas outlet is parallel to a plane where the opening is located, and two side edges of the gas outlet in a width direction of the chamber body are symmetrically arranged relative to the central axis of the wafer stage.

18. The oxidation device of claim 17, wherein the tube body is a gradually expanding structure, an expanded end of the tube body forms the gas outlet, and a contracted end of the tube body forms the gas inlet, wherein a diameter of the gas outlet in the width direction of the chamber body is larger than a diameter of the gas inlet in the width direction of the chamber body.

19. The oxidation device of claim 12, wherein a central axis of the opening is staggered with a central axis of the wafer stage, and an end surface of the gas outlet is parallel to a height direction of the chamber body and inclined relative to an end surface of the opening.

20. The oxidation device of claim 19, wherein the tube body is a gradually expanding structure, an expanded end of the tube body forms the gas outlet, and a contracted end of the tube body forms the gas inlet, wherein a diameter of the gas outlet in the width direction of the chamber body is larger than a diameter of the gas inlet in the width direction of the chamber body.
